(19) United States
(12) Patent Application Publication
(10) Pub. No.: US 2011/0051338 A1
(43) Pub. Date: Mar. 3, 2011

(54) Display Apparatus

(75) Inventors: Masaya NAKAMICHI, Kizugawa-shi (JP); Shohei TAKAHASHI, Osaka (JP)

(73) Assignee: SANYO ELECTRIC CO., LTD., Osaka (JP)

(21) Appl. No.: 12/871,973

(22) Filed: Aug. 31, 2010

(30) Foreign Application Priority Data
Aug. 31, 2009 (JP) 2009-200863

(51) Int. Cl. H05K 5/00

(52) U.S. Cl. 361/679.01

(57) ABSTRACT

A display apparatus includes a display panel, a housing, a seal member, and a groove. The housing is provided with the display panel therein, and includes a front housing forming member and a rear housing forming member. The front housing forming member is provided with an image display window at a position in front of the display panel. The seal member is provided between bonding surfaces of the two housing forming members so as to surround the display panel. The groove is provided in the bonding surface of the front housing forming member or the rear housing forming member along the seal member.

The Japanese patent application Number 2009-200863, upon which this patent application is based, is hereby incorporated by reference.

### BACKGROUND OF THE INVENTION

1. Field of the Invention

The present invention relates to a display apparatus with a waterproof structure.

2. Description of Related Art

In recent years, flat panel display apparatuses for outdoor installation have appeared. In order to install such an apparatus outside permanently, it is considered to form an accommodation chamber 110 inside a housing 100 having a waterproof structure to accommodate an image display panel 120 in the chamber 110 as shown in FIG. 5.

In particular, the housing 100 comprises a front housing forming member 101 and a rear housing forming member 102 which are bonded together. The member 101 is made of a glass material and forms a front wall of the housing 100. Between bonding surfaces of the two members 101, 102, a seal member 130 is intervened so as to extend and surround the chamber 110. A gasket made of silicon rubber or the like is employed as the member 130. Therefore, the housing 100 has a waterproof structure which protects a space inside the chamber 110 from water, and as a result, the panel 120 in the chamber 110 is protected from weather and dust.

In the chamber 110, the panel 120 is accommodated so that its screen 121 faces the front wall of the housing 100. Therefore, the screen 121 of the panel 120 is viewable from outside of the housing 100 (i.e. front side of the housing 100) through the member 101 which is made of a glass material.

However, in the apparatus described above, when a large volume of water enters between the bonding surface of the members 101, 102 from outside of the housing 100, some of the water might intrude into the chamber 110 via the member 130.

In order to solve this problem, by employing an additional seal member 131 between the above mentioned bonding surfaces, it can prevent water from intruding into the chamber 110, as shown in FIGS. 6 and 7. However, in this structure, extra seal member is needed. Since the gasket used for these members 130, 131 is expensive, it increases manufacturing cost of the apparatus.

### SUMMARY OF THE INVENTION

A display apparatus according to the present invention comprises a display panel; a housing provided with the display panel therein, wherein the housing includes a front housing member and a rear housing member, and the front housing member has an image display window in front of the display panel; a seal member provided between bonding surfaces of the front and the rear housing members so as to surround the display panel; and a groove provided along the seal member on the bonding surface of either the front housing member or the rear housing member.

### BRIEF DESCRIPTION OF THE DRAWINGS

FIG. 1 is a perspective view of a display apparatus in accordance with an embodiment of the present invention seen from a front side;

FIG. 2 is a front view of a housing included in the display apparatus;

FIG. 3 is a perspective view of the area A shown in FIG. 2 seen from below;

FIG. 4 is a cross sectional view taken along the line B-B shown in FIG. 2;

FIG. 5 is a front view showing an example of other display apparatus;

FIG. 6 is a front view showing another example of other display apparatus; and

FIG. 7 is a cross sectional view taken along the line C-C shown in FIG. 6.

### DETAILED DESCRIPTION OF THE PREFERRED EMBODIMENT

A display apparatus according to an embodiment of the present invention is discussed in detail below with reference to drawings.

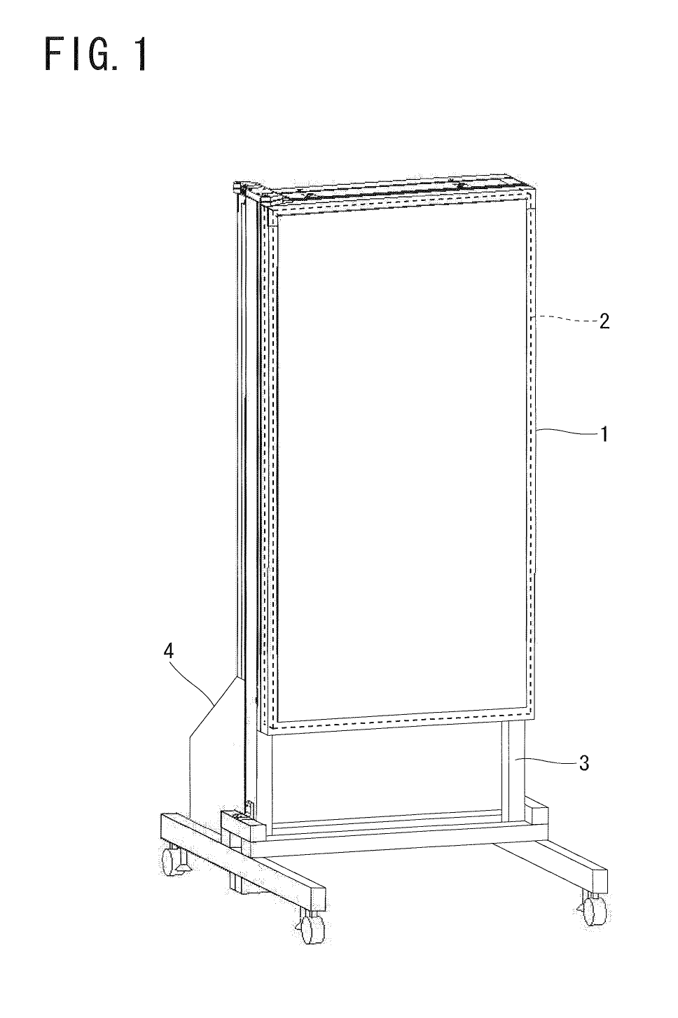

As shown in FIG. 1, the display apparatus comprises a housing 1, a liquid crystal display panel 2 arranged inside the housing 1, a support base 3 for supporting the housing 1, and a cooling device 4. To the support base 3, casters are attached.

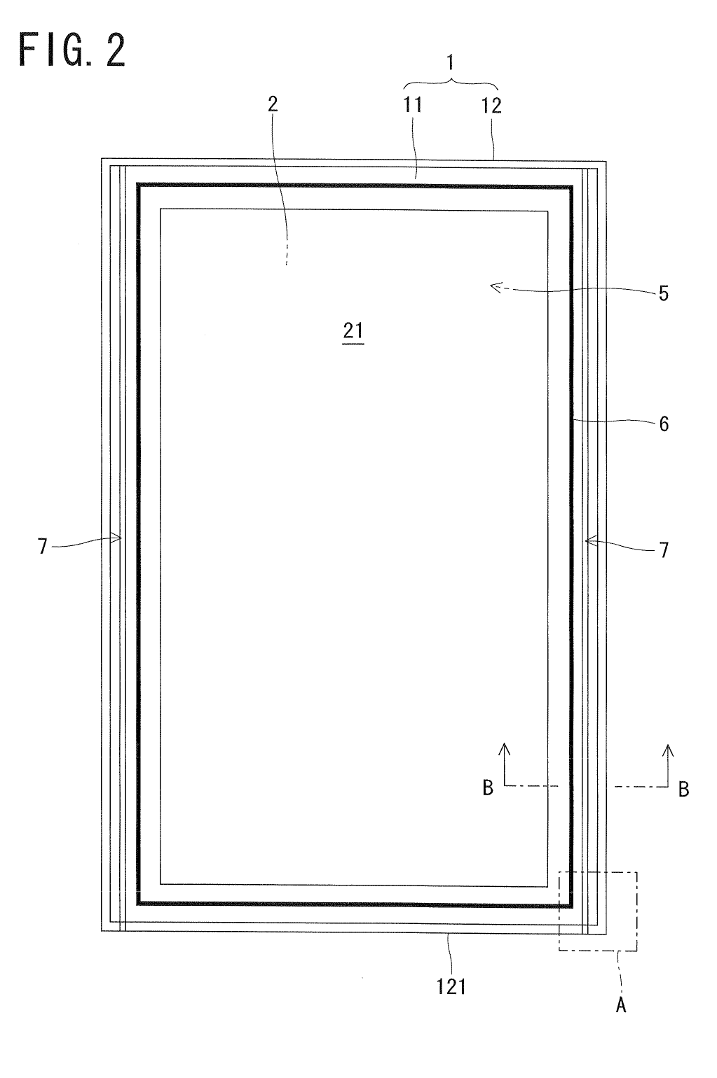

As shown in FIG. 2, the housing 1 comprises a front housing member 11 and a rear housing member 12 which are bonded together, and the housing 1 has an accommodation chamber 5 in its inside. The chamber 5 is a space defined by bonding the members 11, 12. Further, the member 11 forms a front wall of the housing 1 and the member 12 forms an upper wall, a lower wall, both side walls (i.e. left side wall and the right side wall) and a rear wall of the housing 1.

In the chamber 5, the panel 2 is accommodated with its screen 21 facing a generally horizontal direction and facing the front wall of the housing 1. The member 11 is made of an optically transparent material such as a glass material. Thereby, an image display window, which enables the screen 21 to be viewable from outside the housing 1, is constituted by a portion of the member 11 where it faces the screen 21. The member 12 is made of a metal such as aluminum.

As shown in FIGS. 2 to 4, a seal member 6 intervenes between a bonding surface of the members 11, 12, so as to extend and surround the chamber 5. A gasket made of silicon rubber or the like is employed as the member 6.

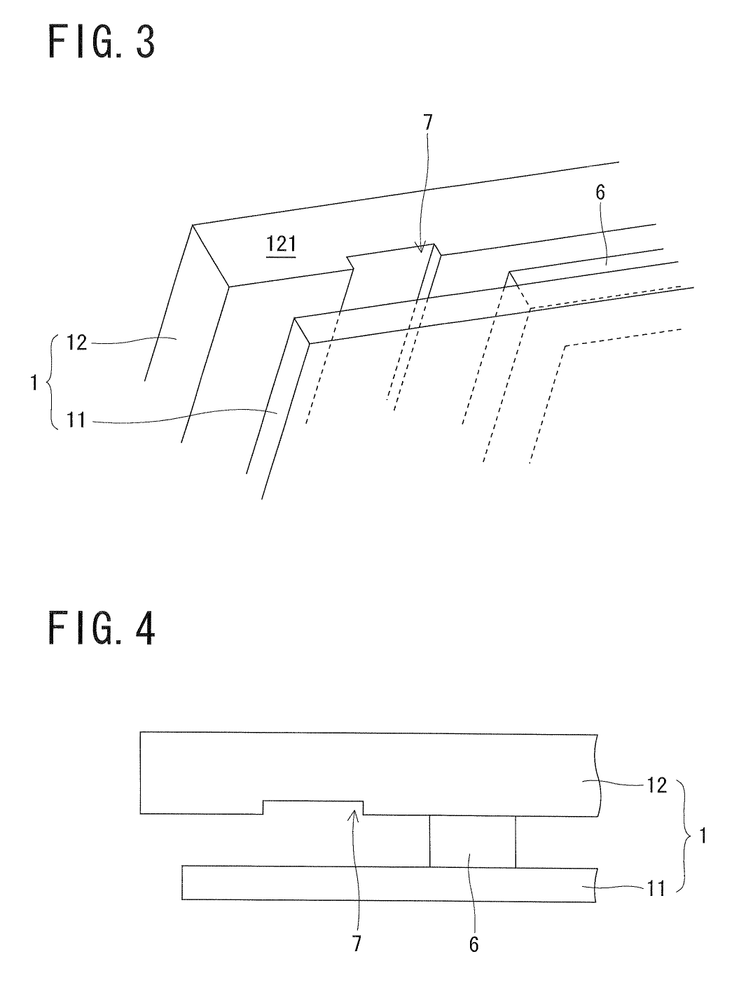

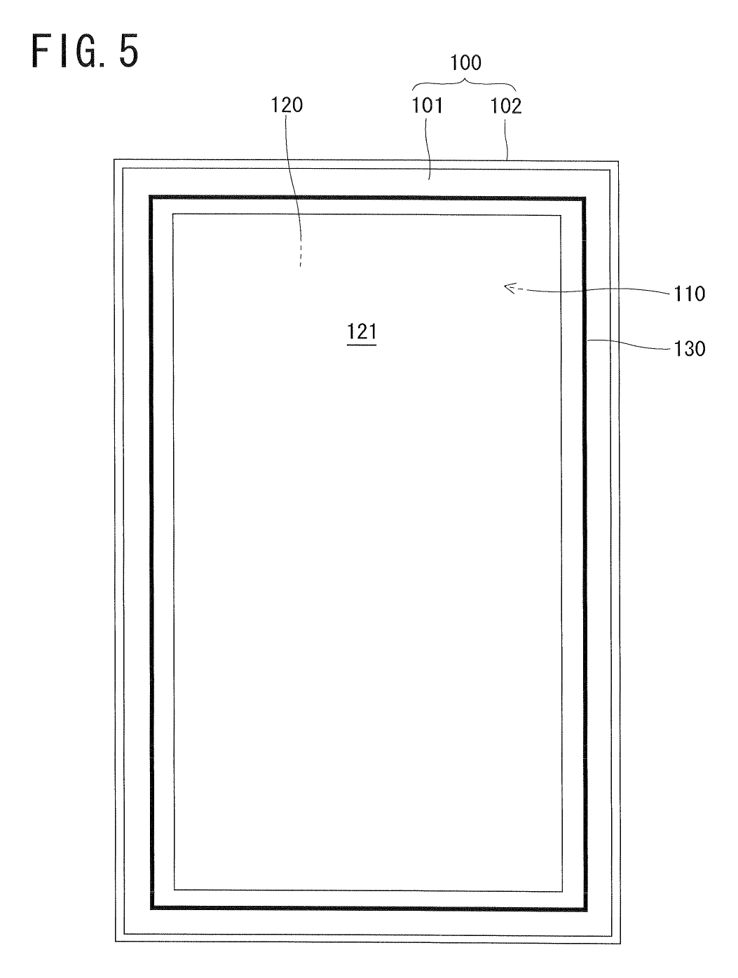

Out of the bonding surfaces of the members 11 and 12, on the bonding surface of the member 12, a pair of grooves 7, 7 extending in a generally vertical direction along the member 6 on both sides of the screen 21 is provided. Both of the grooves 7, 7 are formed outside an area where the member 6 adheres. The grooves 7, 7 extend along the member 6 to a lower end surface 121 of the member 12, and the end parts of the grooves 7, 7 forms an opening on the surface 121 as shown in FIG. 3.

The cooling device 4 collects the heat in the chamber 5 to lower the temperature in the chamber 5.

According to the apparatus described above, a gap between the bonding surfaces of the members 11, 12 is sealed by the member 6. Therefore, a space inside the chamber 5 is sealed, and the housing 1 can have a waterproofing structure which protects the space inside the chamber 5 from water.

Since the space in the chamber 5 is thus sealed, it makes the panel 2 accommodated in the chamber 5 does not contact outside air easily. Therefore, the panel 2 in the chamber 5 is protected from weather and dust, during an outdoor installation of the apparatus.

On the other hand, when the space inside the chamber 5 is sealed, heat generated from the panel 2 stays inside the chamber 5, and the temperature in the chamber 5 is easily raised. Thus, in the apparatus described above, the device 4 is provided in order to collect the heat inside the chamber 5. Thus, the temperature increase in the chamber 5 is inhibited, and as a result, the temperature increase of the panel 2 is inhibited, so that the function of the panel 2 is maintained in normal state.

Also, in the apparatus described above, water which has entered between the bonding surfaces of the two members 11, 12 is captured by the pair of grooves 7, 7 before reaching the member 6. Therefore, even if a large volume of water enters between the bonding surfaces, only a little water reaches the member 6. Therefore, water hardly passes through the member 6 to intrude into the chamber 5, and as a result, the housing 1 has a high waterproofing property.

Further, in the apparatus described above, water captured by the pair of grooves 7, 7 flows downward through inside the groove 7 due to gravity, and emitted outside the housing 1 through the end parts of the groove 7. Therefore, even if the volume of water entering between the bonding surfaces of the members 11, 12 is large, water captured by the grooves 7, 7 does not easily leak out from the groove 7, and as a result, the waterproofing property of the housing 1 does not deteriorate easily.

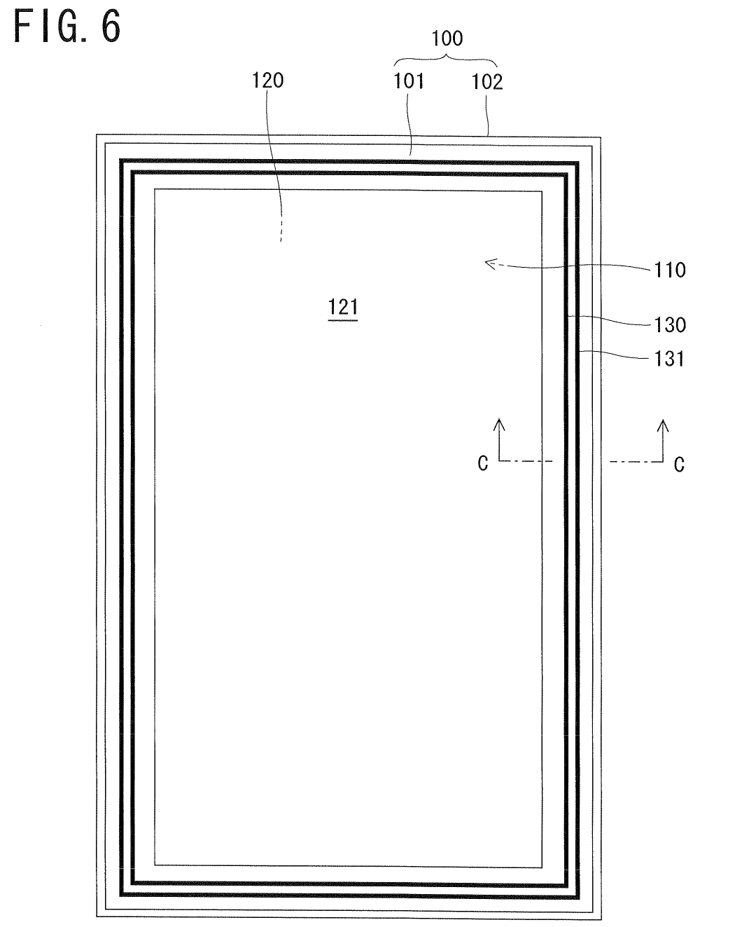

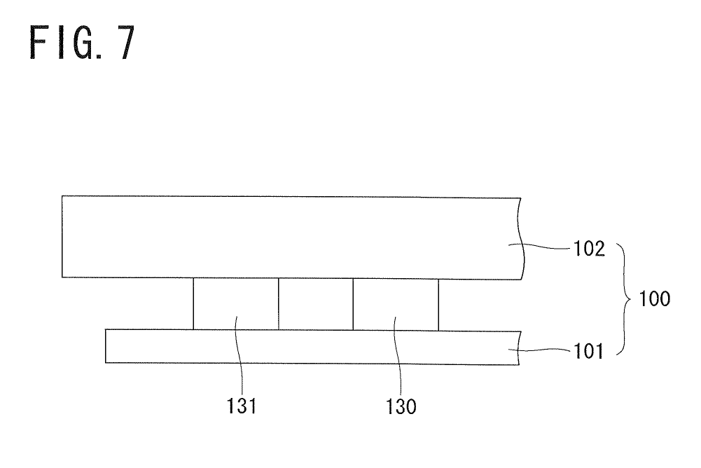

Further, according to the above described apparatus, since it only requires a forming of the pair of grooves 7, 7 in the member 12, increase in the manufacturing cost for enhancing the waterproofing property of the housing 1 is reduced compared to the structure having the seal member 131 instead of the grooves 7, 7 as shown in FIG. 6.

Therefore, according to the apparatus described above, a construction having a high waterproofing property is realized without an excessive increase of the manufacturing cost.

The present invention is not limited to the foregoing embodiment in construction but can be modified variously within the technical range set forth in the appended claims.

For example, in the embodiment described above, the pair of grooves 7, 7 is provided only in the bonding surface of the member 12, however, the present invention is not limited to this structure. The grooves 7, 7 may be provided only in the bonding surface of the member 11, or the grooves 7, 7 may be provided in both the bonding surfaces of the two members 11, 12.

The structure employed in the display apparatus described above can be applied not only to the display apparatus having the panel 2, but also to display apparatuses with various image display panels such as a plasma display, or an organic EL (Electro-Luminescence) display.

What is claimed is:

1. A display apparatus comprising:
a display panel;
a housing provided with the display panel therein, wherein the housing includes a front housing member and a rear housing member, and the front housing member has an image display window in front of the display panel;
a seal member provided between a bonding surface of the front and the rear housing members so as to surround the display panel; and
a groove provided along the seal member on the bonding surface of either the front housing member or the rear housing member.

2. The display apparatus according to claim 1, wherein the groove is provided outside the seal member.

3. The display apparatus according to claim 1, wherein the groove extends along the seal member to an end surface of the housing forming member, and an end part of the groove opens on the end surface of the housing forming member.

4. The display apparatus according to claim 3, wherein the display panel is arranged with a screen thereof facing a generally horizontal direction and the groove extends in a generally vertical direction on both sides of the screen of the display panel.
